(19) United States
(12) Patent Application Publication
(10) Pub. No.: US 2024/0063050 A1
(43) Pub. Date: Feb. 22, 2024

(54) CERAMIC WAFER WITH SURFACE SHAPE AND MANUFACTURING THEREOF

(71) Applicant: Hong Chuang Applied Technology Co., Ltd., Zhubei City (TW)

(72) Inventors: YAN-KAI ZENG, Zhubei City (TW); BAI-XUAN JIANG, Zhubei City (TW); RUI-FENG JIANG, Zhubei City (TW)

(21) Appl. No.: 18/071,120

(22) Filed: Nov. 29, 2022

(30) Foreign Application Priority Data
Aug. 16, 2022 (TW) 111130738

(51) Int. Cl. H01L 21/687; C04B 35/64; C04B 41/53

(52) U.S. Cl. CPC H01L 21/68757; C04B 35/64; C04B 41/5346; C04B 41/5353; C04B 2235/612

(57) ABSTRACT

The present invention provides a ceramic wafer with a surface shape and a manufacturing method thereof. The ceramic wafer has an upper surface and a lower surface, and at least one of the upper surface and the lower surface has an irregular surface shape. The total thickness variation (TTV) value between the two surfaces ranges from 0.1 to 100 μm. The ceramic wafer with the surface shape of the present invention, by controlling the total thickness variation of the wafer, not only helps the coating, but also improves the flow of the fluid, and can improve the bonding force of the coating and reduce the surface defects in the subsequent process.

### BACKGROUND OF THE INVENTION

### 1. Technical Field

The present invention is related to a ceramic wafer, and in particular, to a ceramic wafer with a surface shape.

### 2. Description of Related Art

The manufacturing process of a general wafer include the grinding process to flatten the surface of wafer and to allow the wafer to have a specific thickness, followed by polishing, in order to prevent any surface roughness of the wafer after grinding, thereby obtaining wafer with a flat surface.

The purpose of grinding is to grind the wafer such that its thickness can be controlled within an acceptable range. In addition, the purpose of polishing is to improve any defects caused by grinding, and to increase the surface flatness, uniformity and planarization of the wafer, such that the wafer surface is smooth and attachment of particles thereon can be reduced. Since wafer defects are mostly caused by particle, original void, residue or scratch on the wafer, the final thickness and surface roughness of the wafer determined by the grinding and polishing processes can also affect the final completion of the wafer. When the thickness of the wafer is too great, it can cause poor heat dissipation; however, when the thickness is too thin, the wafer can be fragile and prone to breakage.

### BRIEF SUMMARY OF THE INVENTION

In view of the above, it can be understood that it is necessary to flatten the wafer surface via processing treatment during conventional wafer manufacturing process. However, the inventor has found that during the manufacturing process of semiconductors, when different fluids (liquids or gases) flow through a wafer surface having different thicknesses, i.e., a ceramic wafer with a surface shape, the flow of the fluid is improved, thereby increasing the thin film yield rate.

Accordingly, the present invention provides a ceramic wafer with a surface shape, and the ceramic wafer is able to facilitate the subsequent film coating process and to improve the ceramic bonding strength.

An objective of the present invention is to provide a ceramic wafer with a surface shape, the ceramic wafer comprising an upper surface and a lower surface, and at least one of the upper surface and the lower surface having a surface shape; wherein a total thickness variation (TTV) value between the upper surface and the lower surface is between 0.1˜100 μm.

According to an embodiment of the present invention, the total thickness variation is between 0.1˜10 μm.

According to an embodiment of the present invention, the surface shape includes any one of the following of a convex front side with a flat back side, a concave front side with a flat back side, an irregular front side with a flat back side, a convex front side with a convex back side, a concave front side with a convex back side, an irregular front side with a convex back side, a convex front side with a concave back side, a concave front side with a concave back side, an irregular front side with a concave back side, a convex front side with an irregular back side, a concave front side with an irregular back side, and an irregular front side with a regular back side.

According to an embodiment of the present invention, a material of the ceramic wafer is selected from any one of the following of aluminum nitride, silicon nitride, aluminum oxide, silicon oxide, and nitrides, oxides or carbides of silicon carbide.

Another objective of the present invention is to provide a manufacturing method for the aforementioned ceramic wafer with a surface shape, and the manufacturing method comprising: (1) performing a high-temperature treatment on a ceramic green with post-processing to generate a ceramic sheet; or (2) providing a ceramic wafer having a surface equipped with a thin film or a circuit for production;

Placing the ceramic sheet or the ceramic wafer for production on a carrier, and performing a processing treatment on an upper surface and a lower surface of the ceramic sheet, thereby forming a ceramic wafer with a surface shape; wherein the processing treatment comprises a grinding process, a polishing process, an etching process, a plasma process or a mechanical machining process.

According to an embodiment of the present invention, the grinding process is a single-side grinding process, and an angle of the carrier is adjusted to perform grinding of a surface of the ceramic wafer with a grinder; or an angle of a grinder or a grinding disk is adjusted or a shape of the grinder angle is controlled to perform grinding on the surface of the ceramic wafer.

According to an embodiment of the present invention, the grinding process is a double-side grinding process, and a shape of the grinding disk is adjusted to perform grinding on a surface of the ceramic wafer.

According to an embodiment of the present invention, the polishing process is a single-side polishing process, and an angle or a shape of a polishing disk is adjusted to perform polishing of a surface of the ceramic wafer.

According to an embodiment of the present invention, the polishing process is a double-side polishing process, and an angle or a shape of a polishing disk is adjusted to perform polishing of a surface of the ceramic wafer.

According to an embodiment of the present invention, the etching process is a dry etching process or a wet etching process.

The advantages of the present invention includes at least the following technical effects: The ceramic wafer with a surface shape of the present invention is able to facilitate the film coating process, and when a fluid flows through a surface of different thicknesses, the flow of the fluid is improved, thereby increasing the thin film yield rate in the subsequent process.

### BRIEF DESCRIPTION OF THE SEVERAL VIEWS OF THE DRAWINGS

The accompanied drawings illustrate the exemplary embodiments of the present invention, and the drawings include:

FIG. 1 shows schematic views of the ceramic wafer with different surface shapes according to an embodiment of the present invention;

FIG. 2 shows schematic views illustrating the single-side grinding method according to an embodiment of the present invention;

FIG. 3 shows schematic views illustrating the double-side grinding method according to an embodiment of the present invention;

FIG. 4 shows schematic views illustrating the single-side polishing method according to an embodiment of the present invention; and

FIG. 5 shows schematic views illustrating the double-side polishing method according to an embodiment of the present invention.

It shall be understood that the technical features of the present invention are not limited to the configuration, techniques and characteristics illustrated in the accompanied drawings.

### DETAILED DESCRIPTION OF THE INVENTION

According to the common operation method, the features and components illustrated in the drawings are not presented in actual scale, and the drawings are provided to facilitate the illustration of the specific features and components related to the present invention only. In addition, identical or similar component signs shown in the drawings refer to similar components and parts.

The following embodiments described shall not be used to overly limit the scope of the present invention. A person with ordinary skill in the art of the present invention any made modifications and changes to the embodiments described in the content of this document without deviating from the principle or scope of the present invention; therefore, such modification and changes shall still be deemed to be within the scope of the present invention.

The term of “one”, “a” or “an” used in the following content shall mean one or more than one, i.e., at least one.

The present invention provide a ceramic wafer with a surface shape, and the ceramic wafer includes an upper surface and a lower surface, and at least one of the upper surface and the lower surface has an irregular surface shape; wherein a total thickness variation (TTV) value between the upper surface and the lower surface is between 0.1˜100 μm, such as, but not limited to, the following: between 0.2 μm˜100 μm, between 0.5 μm˜100 μm, between 1.5 μm˜100 μm, between 3.5 μm˜100 μm, between 5.5 μm˜100 μm, between 9.5 μm˜100 μm, between 15 μm˜100 μm, between 35 μm˜100 μm, between 55 μm˜100 μm, between 0.2 μm˜50 μm, between 0.2 μm˜60 μm, between 0.1 μm˜80 μm, between 0.1 μm˜90 μm, between 0.1 μm˜55 μm, between 0.1 μm˜30 μm, between 0.1 μm˜20 μm, between 0.1 μm˜15 μm, between 0.1 μm˜10 μm, between 0.2 μm˜15 μm, between 0.2 μm˜25 μm, between 0.2 μm˜40 μm, between 0.1 μm−1 μm, between 0.1 μm˜0.8 μm, between 0.1 μm˜0.6 μm, between 0.1 μm˜0.4 μm or between 0.1 μm˜0.2 μm. In a preferred embodiment, the total thickness variation (TTV) value is between 0.1˜10 μm, such as, but not limited to, the following: between 0.2 μm˜10 μm, between 0.5 μm˜10 μm, between 0.8 μm˜10 μm, between 1 μm˜10 μm, between 3 μm˜10 μm, between 5 μm˜10 μm, between 7 μm˜10 μm, between 9 μm˜10 μm, between 1 μm˜6 μm, between 3 μm˜7 μm, between 4 μm˜8 μm, between 5 μm˜9 μm, between 6 μm˜7 μm, between 6 μm˜8 μm, between 6 μm˜9 μm, between 7 μm˜8 μm, between 7 μm˜9 μm or between 8 μm˜9 μm.

The “total thickness variation (TTV)” described here refers to a thickness variation between the location of the greatest thickness and the location of smallest thickness of a wafer. To be more specific, under the condition where a wafer is attached to a reference plane it refers to the difference between the largest value and the smallest value of its thickness away from the reference plane.

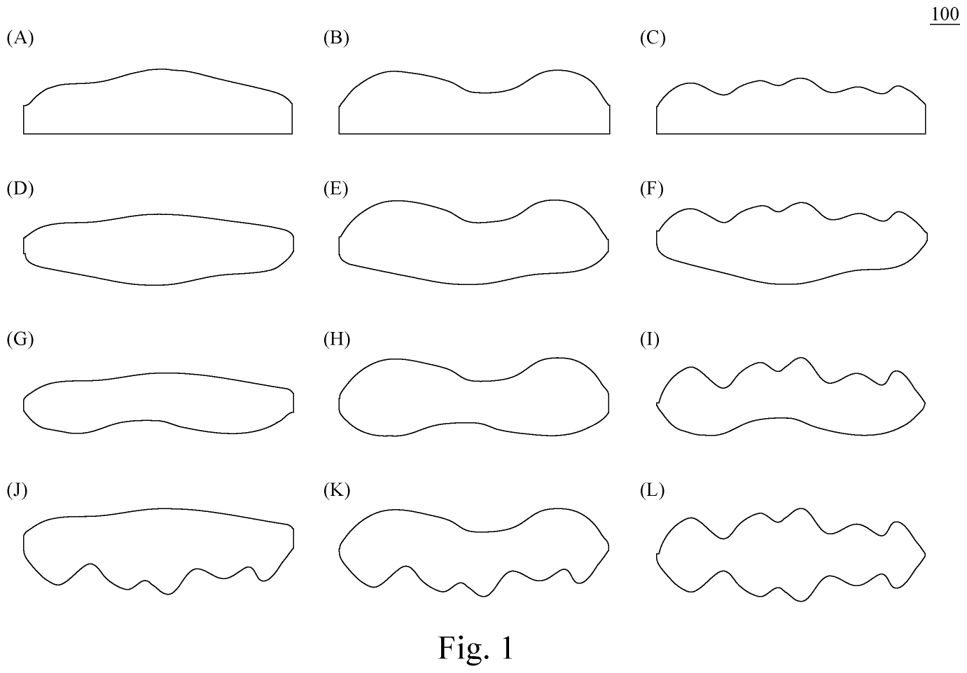

As shown in FIG. 1, the upper surface of the ceramic wafer 100 refers to the front side of the ceramic wafer 100, and the lower surface of the ceramic wafer 100 refers to the back side of the ceramic wafer 100. In addition, at least one of the upper surface and the lower surface has an irregular surface shape. In a preferred embodiment, the upper surface has a concave surface, a convex surface or an irregular shape; and the lower surface has a flat surface, a concave surface or a convex surface. Accordingly, the shape of the ceramic wafer 100 includes but not limited to any one of the following of a convex front side with a flat back side (A), a concave front side with a flat back side (B), an irregular front side with a flat back side (C), a convex front side with a convex back side (D), a concave front side with a convex back side (E), an irregular front side with a convex back side (F), a convex front side with a concave back side (G), a concave front side with a concave back side (H), an irregular front side with a concave back side (I), a convex front side with an irregular back side (J), a concave front side with an irregular back side (K), and an irregular front side with a regular back side (L). The ceramic wafer 100 with a surface shape is able to facilitate the subsequent film coating process and to improve the ceramic bonding strength.

The “ceramic wafer” described in this content refers to a polycrystal material or a single-crystal material, and its composition refers to ceramic or semiconductor material. In addition, “ceramic” refers to an inorganic non-metal solid material, including silicates, oxides, carbides, nitrides, sulfides, borides, obtained from a metallic and non-metallic compound via a high-temperature treatment. Preferably, it includes but not limited to a group selected from any one of aluminum nitride, aluminum oxide, silicon carbide and silicon nitride.

In a preferred embodiment of the present invention, the material of the ceramic wafer is selected from any one of the following of aluminum nitride, silicon nitride, aluminum oxide, silicon oxide, and nitrides, oxides or carbides of silicon carbide. Since ceramic has the characteristics of high dielectric constant, insulation, high thermal conductivity, heat resistant and excellent heat dissipation, and particularly, it demonstrates stable performance under high humidity, accordingly, it is applicable to the manufacturing of electronic products. Furthermore, ceramic wafer has excellent Processability such that it can be used for manufacturing wafer sizes of high precision.

The “single-crystal or polycrystal material” described in this content refers to moocrystalline or polycrystalline materials respectively. The difference refers to that when a molten mono-material is cured, the atoms are arranged into a lot of crystal nuclei of diamond lattice. if the crystal nuclei grow into crystals with crystal planes of the same orientation, it becomes a single-crystal material. On the contrary, if the nuclei grow into crystals with crystal planes in different orientations, it becomes a polycrystal material.

In addition, the present invention provides a manufacturing method for the aforementioned ceramic wafer with a surface shape according, and the manufacturing method comprises the following steps:

Step 1. (1) Performing a high-temperature treatment on a ceramic green with post-processing to generate a ceramic sheet; or (2) providing a ceramic wafer having a surface equipped with a thin film or a circuit for production;

Step 2. Placing the ceramic sheet or the ceramic wafer for production on a carrier, and performing a processing treatment on an upper surface and a lower surface of the ceramic sheet, thereby forming a ceramic wafer with a surface shape; wherein the processing treatment comprises a grinding process, a polishing process, an etching process, a plasma process or a mechanical machining process.

In Step 1-(1), the method for generating a ceramic green comprises the following steps of forming the ceramic green from a ceramic grain via a process, and performing the high-temperature treatment on the ceramic green with processing to form a ceramic sheet.

The type of processing treatment for the wafer described in this content includes: chemical processing, mechanical processing and chemical-mechanical processing.

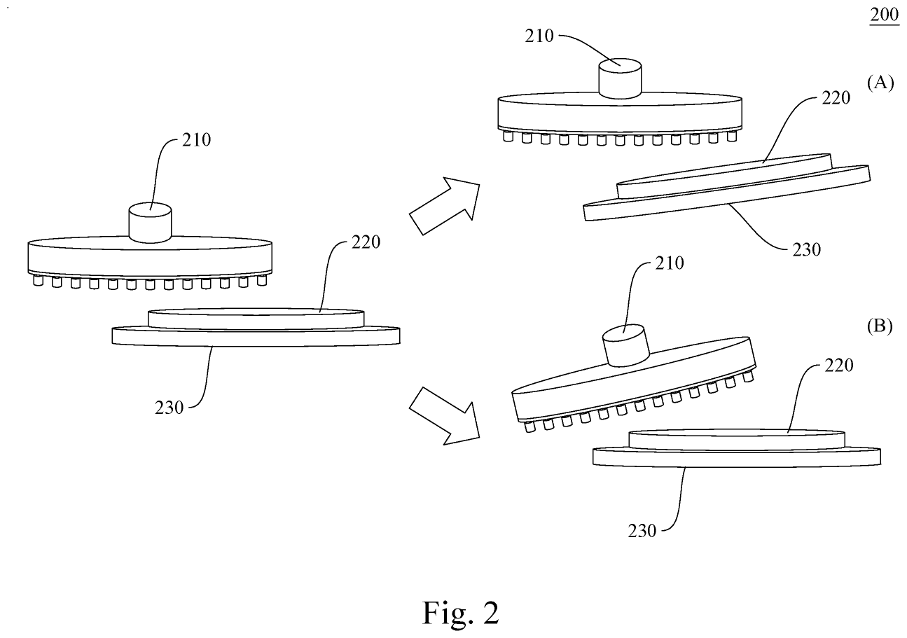

As shown in FIG. 2, in a preferred embodiment, the grinding process of the present invention refers to a single-side grinding process 200. To be more specific, the ceramic wafer 220 is placed on a high-speed rotary machine equipped with a carrier 230, and the ceramic wafer 230 is secured at the rotational center of the carrier 230, followed by performing rotation to allow the carrier 230 to press against the grinder 210 firmly, and then use the grinder to perform grinding on a surface of the wafer 220 slowly. In addition, for the single-side grinding process, an angle of the carrier 230 is adjusted to perform grinding (A) of the surface of the ceramic wafer 220 with a grinder 210; or an angle of a grinder 210 is adjusted or a shape (B) of the grinder 210 angle is controlled to perform grinding on the surface of the ceramic wafer 220, in order to control the surface shape of the ceramic wafer 220. If single-side grinding method is used, the back side of the ceramic wafer can be applied with UV adhesive, hot-melt adhesive or coating adhesive, in order to increase its uniformity.

The “carrier” described in this content may refer to a vacuum suction disk or a clamping disk. The vacuum suction disk forms a vacuum between the ceramic wafer and the carrier in order to suck and hold the ceramic wafer. The clamping disk circumferentially clamp and hold the ceramic wafer, in order to secure the ceramic wafer at an appropriate position.

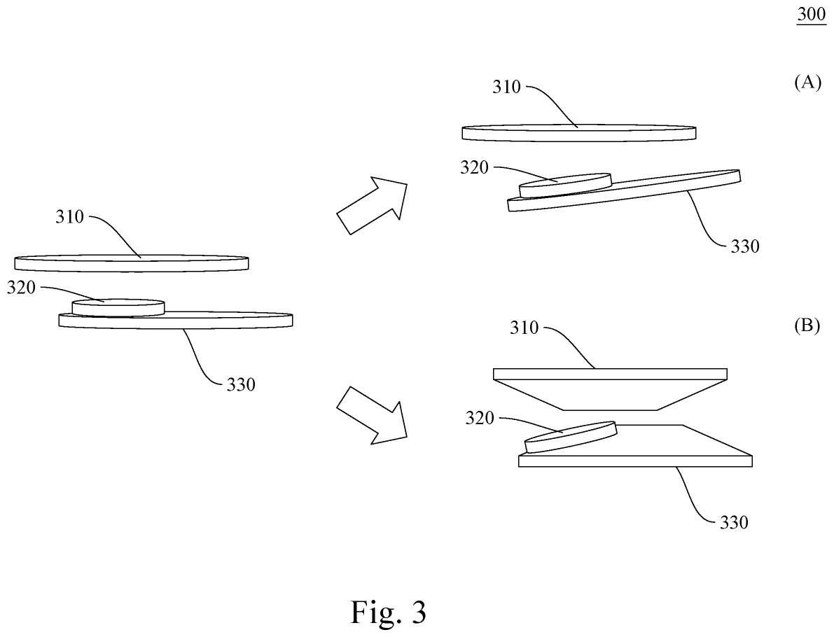

As shown in FIG. 3, in a preferred embodiment, the grinding process of the present invention refers to a double-side grinding process 300. To be more specific, the ceramic wafer 320 is placed on a high-speed rotary machine equipped with a lower grinding disk 330, and the ceramic wafer 320 is secured at the rotational center of the lower grinding disk 330. In addition, the upper grinding disk 310 and the lower grinding disk 330 are used to press against the ceramic wafer 320 firmly in order to perform the double-side processing. Furthermore, for the double-side grinding process, an angle of the grinding disk (A) or a shape of the grinding teeth (B) (not shown in the drawings) on the grinding disk is adjusted to perform grinding of the surface of the ceramic wafer, in order to control the surface shape of the ceramic wafer 320.

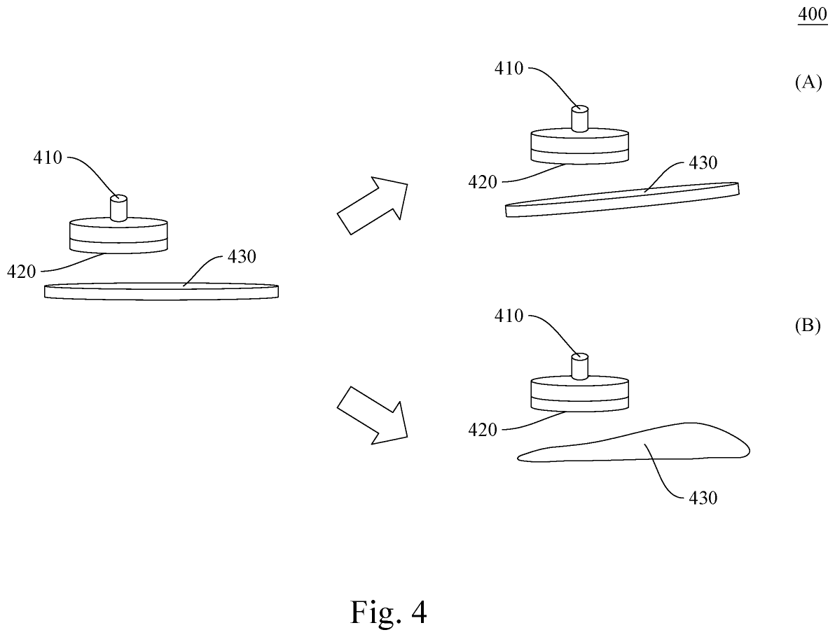

As shown in FIG. 4, in a preferred embodiment, the polishing process of the present invention refers to a single-side polishing process 400. To be more specific, the ceramic wafer 420 is placed on a high-speed rotary machine equipped with a polishing disk 430, and the ceramic wafer 420 is secured at the rotational center of the polishing disk 430, followed by performing rotation to allow the polishing disk 430 to press against the grinder 410 firmly, and then use the polishing disk 430 to perform polishing on a surface of the wafer 420 slowly. In addition, for the single-side polishing process, an angle (A) of the polishing disk 430 or a shape (B) of the polishing disk 430 is adjusted to perform polishing of the surface of the ceramic wafer, such that through the adjustment of the angle or shape of the polishing disk, the surface shape of the ceramic wafer can be controlled.

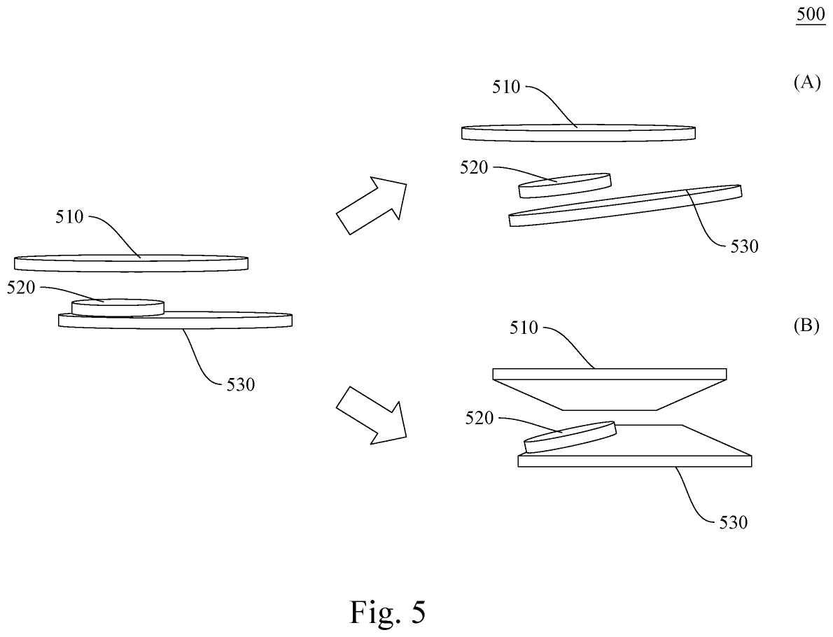

As shown in FIG. 5, in a preferred embodiment, the polishing process of the present invention refers to a double-side polishing process 500. To be more specific, the ceramic wafer 520 is placed on a high-speed rotary machine equipped with a lower polishing disk 530, and the ceramic wafer 520 is secured at the rotational center of the lower polishing disk 530. In addition, the upper polishing disk 510 and the lower polishing disk 530 are used to press against the ceramic wafer 520 firmly in order to perform the double-side processing. In addition, for the double-side polishing process, an angle (A) or a shape (B) of the polishing disk is adjusted to perform polishing of the surface of the ceramic wafer, such that through the adjustment of the angle or shape of the upper and lower polishing disks, the surface shape of the ceramic wafer can be controlled.

In a preferred embodiment, the etching process is a dry etching process or a wet etching process. The ceramic wafer is immersed in an etching solution, allowing the surface to be etched to form a ceramic wafer with a surface shape. In a preferred embodiment, the present invention can also adopt the method of striking a plasma on the surface of the ceramic wafer in order to form a ceramic wafer with a surface shape.

### EMBODIMENTS

The following exemplary and non-restrictive embodiments of the present invention are provided, and the purpose of the following disclosure is to illustrate various measures and technical effects of the present invention.

In addition, exemplary and non-restrictive manufacturing methods of the ceramic wafer with a surface shape are provided in the following. According to a method similar to the method disclosed above, three types of exemplary and non-restrictive embodiments of the ceramic wafer with a surface shape are prepared (Embodiments 1˜3) and three comparison examples of the ceramic wafer with a surface shape are provided (Comparison Examples 1˜3). However, it shall be noted that the specific methods adopted for the preparation of the Embodiments 1˜3 and the Comparison Examples 1˜3 may be different from the method disclosed above in one or more aspects.

Measurement of Surface Defects

For the present invention, the surface defect of the aforementioned ceramic wafer is measured. To be more specific, the measurement process refers to: after perform film coating of the ceramic wafer, use microscope to inspect and measure the quantity, size and shape of defects.

The Embodiments 1˜3 and the Comparison Examples 1˜3 are evaluated in order to determine the property of the ceramic wafer with a surface shape. Table 1 provides the general description of the attributes of The Embodiments 1˜3 and the Comparison Examples 1˜3 as well as the defects of the ceramic wafer after film coating.

TABLE 1

| | Embodiment | Embodiment | Embodiment | Comparison | Comparison | Comparison |
|---|---|---|---|---|---|---|
| | 1 | 2 | 3 | Example 1 | Example 2 | Example 3 |
| Defect | 300 | 10 | 15 | 410 | 400 | 350 |
| Quantity | | | | | | |
| (defects) | | | | | | |
| Total | 0.1 | 5 | 10 | 0.02 | 0.05 | 0.08 |
| Thickness | | | | | | |
| Variation | | | | | | |
| (TTV)/um) | | | | | | |
| Defect | 25 | 5 | 6 | 26 | 28 | 28 |
| Size (um) | | | | | | |

According to the aforementioned measurement result, Embodiment 1 has approximately 300 surface defects; Embodiment 2 has 10 surface defects; Embodiment 3 has 15 surface defects. In comparison to Comparison Examples 1 to 3, Embodiments 1 to 3 have smaller defect quantities and the defect sizes are smaller

According to the measurement result of specific embodiments of the present invention, it can be understood that through the control of the total thickness variation of the ceramic wafer, the ceramic wafer provided by the present invention is able to demonstrate greater post-coating surface defects, and the overall yield rate of the ceramic wafer can be improved.

In view of the above, for the ceramic wafer with a surface shape of the present invention, when the surface has an irregular shape and the total thickness variation (TTV) is between 0.1˜100 μm, it is able to facilitate the film coating process. In addition, when the fluid flows through a surface of different thicknesses, the flow of the fluid is improved, thereby increasing the ceramic bonding strength in the subsequent process.

All of the ranges described in this content includes each specific range within the given range and a combination of sub-ranges within the given range. In addition, unless otherwise specified, all of the ranges described in this content include the end point or value of the range described. Accordingly, for example, a range of 1˜5 shall specifically include 1, 2, 3, 4 and 5, and the sub-ranges of, such as, 2˜5, 3˜5, 2˜3, 2˜4, 1˜4, and so on.

All of the publications and patent applications cited by this document are incorporated into this content via citation, and for any and all of the objectives, each publication or patent application is explicitly and individually described and incorporated into this content via citation. In case where there is any discrepancy between this content and any publication or patent application incorporated into this content, the description provided in this content shall prevail.

The term “comprising”, “comprise”, “having” “have”, “including” and “include” described in this content shall have an open and non-restrictive meaning. The term “one” or “a” shall be interpreted to cover the meanings of both plural and singular. The term “one or more” refers to “at least one”; therefore, it includes one feature or mixed/combined features.

Except for operating embodiments or areas specifically indicated, the term of “approximately” or “approximate” can be used for numeric values representing the quantity of composition and/or reaction condition in all situations, and it means that the it is within ±5% of the numeric value indicated. The term “basically excluding” or “substantially excluding” described in this content shall mean the reduction of approximately 2% of a specific feature. The scope of the claims may be negatively exclude all elements or features described affirmably in this content.

The above provides detailed description of the present invention. Nevertheless, it shall be understood that the above description is provided to illustrate the preferred embodiments of the present invention only, and it shall not be treated as limitation to the implementation scope of the present invention. All equivalent changes and modifications made based on the scope of the claims of the present invention shall be considered to be within the scope of the claims of the present invention.

What is claimed is:

1. A ceramic wafer with a surface shape, the ceramic wafer comprising an upper surface and a lower surface, and at least one of the upper surface and the lower surface having a surface shape;
wherein a total thickness variation (TTV) value between the upper surface and the lower surface is between 0.1˜100 μm.

2. The ceramic wafer with a surface shape according to claim 1, wherein the total thickness variation is between 0.1˜10 μm.

3. The ceramic wafer with a surface shape according to claim 1, wherein the surface shape includes any one of the following of a convex front side with a flat back side, a concave front side with a flat back side, an irregular front side with a flat back side, a convex front side with a convex back side, a concave front side with a convex back side, an irregular front side with a convex back side, a convex front side with a concave back side, a concave front side with a concave back side, an irregular front side with a concave back side, a convex front side with an irregular back side, a concave front side with an irregular back side, and an irregular front side with a regular back side.

4. The ceramic wafer with a surface shape according to claim 1, wherein a material of the ceramic wafer is selected from any one of the following of aluminum nitride, silicon nitride, aluminum oxide, silicon oxide, and nitrides, oxides or carbides of silicon carbide.

5. A manufacturing method for the ceramic wafer with a surface shape according to claim 1, the manufacturing method comprising:
i. (1) performing a high-temperature treatment on a ceramic green with post-processing to generate a ceramic sheet; or (2) providing a ceramic wafer having a surface equipped with a thin film or a circuit for production;
ii. placing the ceramic sheet or the ceramic wafer for production on a carrier, and performing a processing treatment on an upper surface and a lower surface of the ceramic sheet, thereby forming a ceramic wafer with a surface shape;
wherein the processing treatment comprises a grinding process, a polishing process, an etching process, a plasma process or a mechanical machining process.

6. The manufacturing method according to claim 5, wherein the grinding process is a single-side grinding process, and an angle of the carrier is adjusted to perform grinding of a surface of the ceramic wafer with a grinder; or an angle of a grinder or a grinding disk is adjusted or a shape of the grinder angle is controlled to perform grinding on the surface of the ceramic wafer.

7. The manufacturing method according to claim 5, wherein the grinding process is a double-side grinding process, and a shape of the grinding disk is adjusted to perform grinding on a surface of the ceramic wafer.

8. The manufacturing method according to claim 5, wherein the polishing process is a single-side polishing process, and an angle or a shape of a polishing disk is adjusted to perform polishing of a surface of the ceramic wafer.

9. The manufacturing method according to claim 5, wherein the polishing process is a double-side polishing process, and an angle or a shape of a polishing disk is adjusted to perform polishing of a surface of the ceramic wafer.

10. The manufacturing method according to claim 5, wherein the etching process is a dry etching process or a wet etching process.
